(19) United States
(12) Patent Application Publication
(10) Pub. No.: US 2026/0198278 A1
(43) Pub. Date: Jul. 9, 2026

(54) INTERCONNECT STRUCTURE INCLUDING CONTACT VIA WITH INCREASED CONTACT AREA TO METAL LINE AND METHOD FOR MANUFACTURING THE SAME

(71) Applicant: TAIWAN SEMICONDUCTOR MANUFACTURING COMPANY, LTD., Hsinchu (TW)

(72) Inventors: Wei-Hao LIAO, Hsinchu (TW); Wei Chih WANG, Hsinchu (TW); Hsi-Wen TIEN, Hsinchu (TW); Chih Wei LU, Hsinchu (TW); Hwei-Jay CHU, Hsinchu (TW); Yu-Teng DAI, Hsinchu (TW); Hsin-Ping CHEN, Hsinchu (TW); Hsin-Chieh YAO, Hsinchu (TW)

(73) Assignee: TAIWAN SEMICONDUCTOR MANUFACTURING COMPANY, LTD., Hsinchu (TW)

(21) Appl. No.: 19/010,989

(22) Filed: Jan. 6, 2025

(51) Int. Cl. H01L 21/768; H01L 23/522

(52) U.S. Cl. CPC H10W 20/089; H10W 20/056; H10W 20/42

(57) ABSTRACT

A method for manufacturing an interconnect structure includes: forming a via opening in a dielectric layer, an inner wall surface of the dielectric layer defining the via opening and having an annular top view shape which has a first dimension in a first plane and a second dimension in a second plane, the first plane intersecting the inner wall surface to form two first lines, the second plane intersecting the inner wall surface to form two second lines; subjecting the inner wall surface to an etching rate modification treatment, so that the inner wall surface has etching rates gradually increasing from each of the first lines to each of the second lines; subjecting the inner wall surface to an etching process, so that the second dimension is elongated to be greater than the first dimension; and forming a contact via in the via opening.

### BACKGROUND

With rapid development of semiconductor technology, an increasing number of devices with different functions are being integrated in an integrated circuit, thereby increasing the complexity of integrated circuit design. For an advanced back-end interconnecting structure, dimension of conductive features (e.g., metal lines and metal vias) therein is relatively small, and pattern density of the conductive features is relatively high. Thus, it is important to reduce the electrical resistance in the advanced back-end interconnecting structure, and to prevent current leakage between two adjacent ones of the conductive features. Therefore, methods for manufacturing the advanced back-end interconnecting structure with low electrical resistance and high reliability are being continuously developed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flow diagram illustrating a method for manufacturing an interconnect structure in accordance with some embodiments.

FIGS. 2A to 10D are schematic views illustrating intermediate stages of the method depicted in FIG. 1 in accordance with some embodiments.

### DETAILED DESCRIPTION

The following disclosure provides many different embodiments, or examples, for implementing different features of the disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “on,” “above,” “top,” “bottom,” “upper,” “lower,” “over,” “beneath,” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

For the purposes of this specification and appended claims, unless otherwise indicated, all numbers expressing amounts, sizes, dimensions, proportions, shapes, formulations, parameters, percentages, quantities, characteristics, or other numerical values used in the specification and claims, are to be understood as being modified in all instances by the term “about” even if the term “about” is not explicitly recited with the values, amounts or ranges. Accordingly, unless indicated to the contrary, the numerical parameters set forth in the following specification and appended claims are not and need not be exact, but may be approximations and/or larger or smaller than specified as desired, may encompass tolerances, conversion factors, rounding off, measurement error, and other factors known to those of skill in the art depending on the desired properties sought to be obtained by the presently disclosed subject matter. For example, the term “about,” when used with a value, can capture variations of, in some aspects ±20%, in some aspects ±10%, in some aspects ±5%, in some aspects ±2.5%, in some aspects ±1%, in some aspects ±0.5%, and in some aspects ±0.1% from the specified amount, as such variations are appropriate to perform the disclosed methods or employ the disclosed compositions and could be understood by those skilled in the art after reviewing the present disclosure.

The term “source/drain portion(s)” may refer to a source or a drain, individually or collectively dependent upon the context.

In common practice, each contact via typically has a circular shape when viewed from above. The present disclosure is directed to a method for manufacturing an interconnect structure which includes a contact via having an elliptical shape rather than a circular shape, so as to increase a contact area between the contact via and a metal line connected thereto, thereby reducing an electrical resistance between the contact via and the metal line.

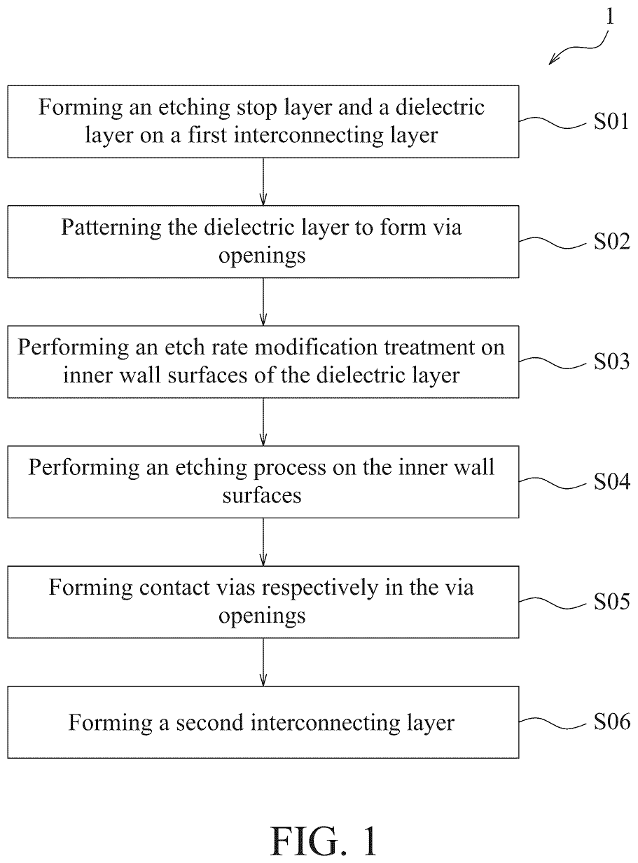

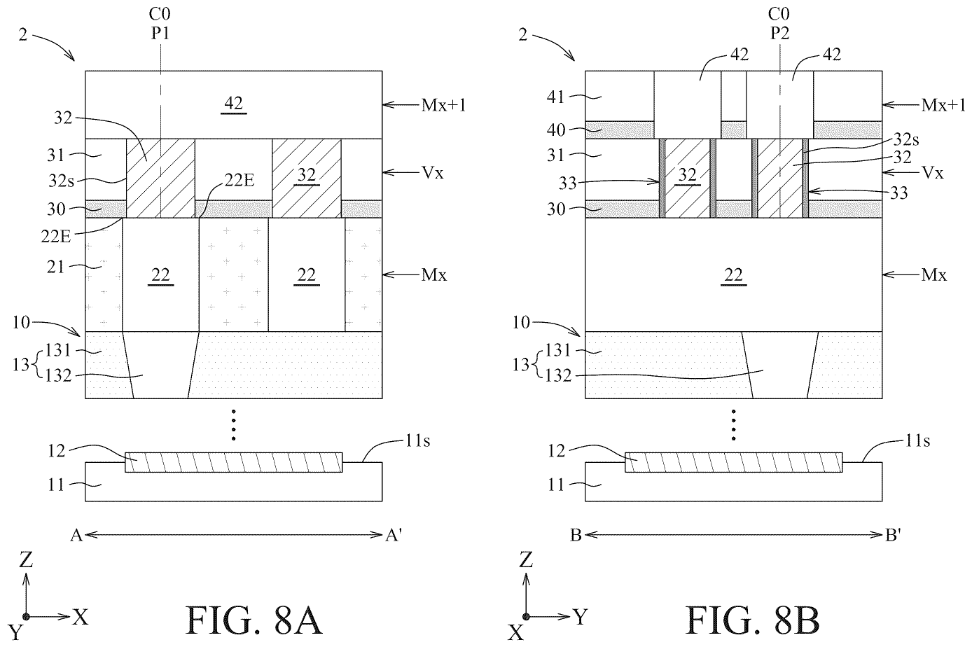

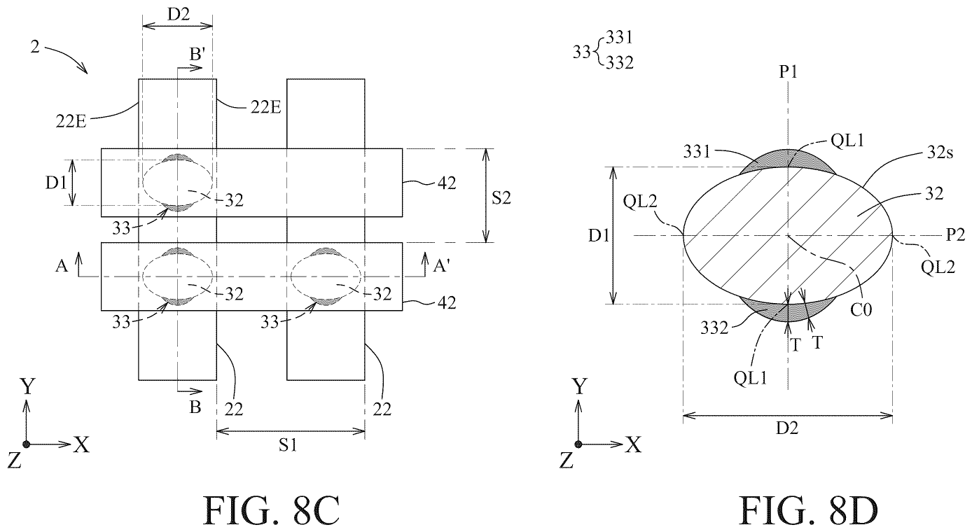

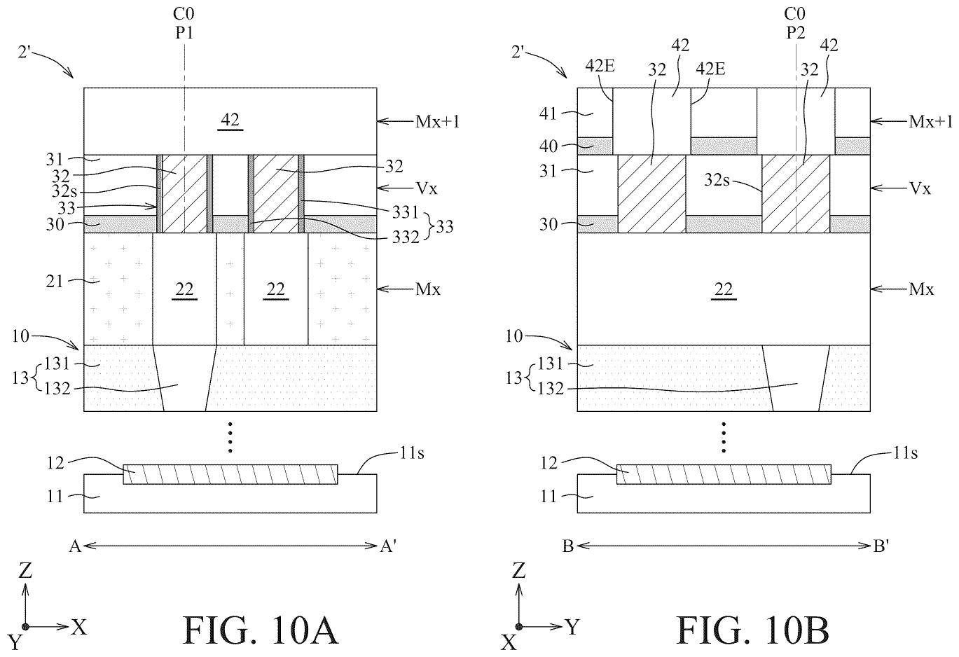

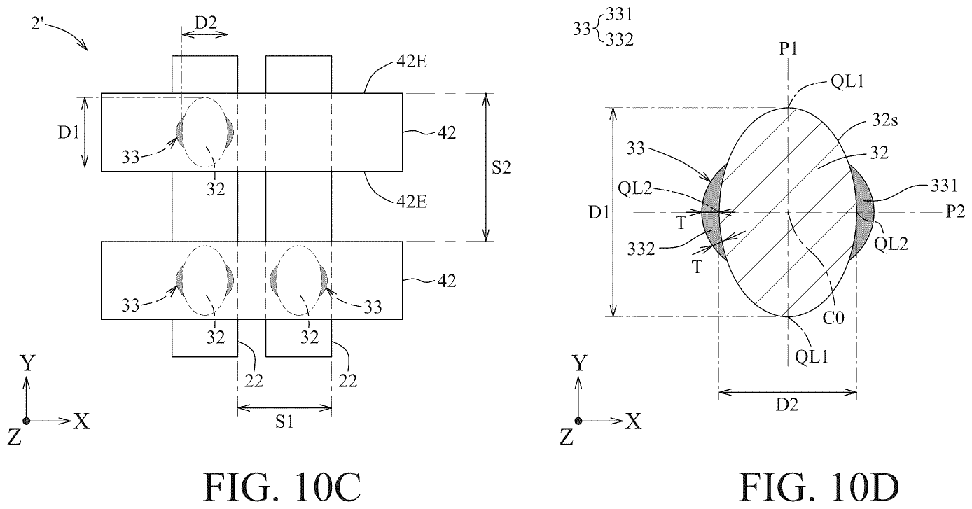

FIG. 1 is a flow diagram illustrating a method 1 for manufacturing an interconnect structure (e.g., an interconnect structure 2 shown in FIGS. 8A to 8C or an interconnect structure 2′ shown in FIGS. 10A to 10C) in accordance with some embodiments. In some embodiments, the interconnect structure is formed on a front side of a base structure 10 (see, for example, FIG. 8A). In some embodiments not shown herein, the interconnect structure may be formed on a back side of the base structure 10 opposite to the front side.

FIG. 8C is a schematic top view illustrating the interconnect structure 2 in accordance with some embodiments, in which contact vias 32, metal lines 22, 42, doped layers 33 are shown and other elements are omitted for the sake of brevity. FIGS. 8A and 8B are schematic sectional views respectively taken along line A-A′ and line B-B′ of FIG. 8C, and further illustrating the elements omitted in FIG. 8C. FIG. 8D is an enlarged fragmentary top view illustrating one of the contact vias 32 shown in FIG. 8C. FIGS. 10A to 10D are schematic views respectively similar to those of FIGS. 8A to 8D, but illustrating the interconnect structure 2′ in accordance with some embodiments. The structural differences between the interconnect structure 2′ and the interconnect structure 2 will be described in the following.

In some embodiments, the base structure 10 is a device wafer including active devices (for example, transistors, diodes, or the like), passive devices (for example, capacitors, inductors, resistors, or the like), memory devices, decoders, amplifiers, or combinations thereof. In some embodiments, the base structure 10 includes a substrate 11, a plurality of semiconductor devices 12 (one of which is exemplarily shown in, for example, FIGS. 8A and 8B) formed on the substrate 11, and an interconnect layer 13 formed on the semiconductor devices 12.

In some embodiments, the substrate 11 may include elemental semiconductor materials (such as crystalline silicon, diamond, or germanium), compound semiconductor materials (such as silicon carbide, gallium arsenide, indium arsenide, or indium phosphide), alloy semiconductor materials (such as silicon germanium, silicon germanium carbide, gallium arsenide phosphide, or gallium indium phosphide), or combinations thereof. In some embodiments, the substrate 11 may be a bulk semiconductor substrate, for example, but not limited to, a bulk substrate of silicon, germanium, silicon germanium, or other suitable semiconductor materials (such as the examples described earlier in the same paragraph). In some other embodiments not shown herein, the substrate 11 may be configured as a semiconductor-on-insulator substrate. Other suitable materials and configurations for the substrate 11 are within the contemplated scope of the present disclosure. In some embodiments, the substrate 11 may be formed with trench isolations (not shown) to separate two adjacent ones of the semiconductor devices 12. In some embodiments, the trench isolations may each be a shallow trench isolation (STI), a deep trench isolation (DTI), or other suitable structures. In some embodiments, the trench isolations may include silicon oxide, silicon nitride, silicon oxynitride, other low-k (low-dielectric constant) dielectric materials, or combinations thereof.

In some embodiments, each of the semiconductor devices 12 may include a transistor, but is not limited thereto. The transistor may be configured as a planar transistor, a fin-type field-effect transistor (FinFET), a gate-all-around field-effect transistor (GAAFET), a forksheet field-effect transistor, a complementary field-effect transistor (CFET), or other transistors with suitable configuration.

In some embodiments, the interconnect layer 13 includes a dielectric layer 131 and conductive features 132 (one of which is exemplarily shown in, for example, FIGS. 8A and 8B) formed in the dielectric layer 131. The semiconductor devices 12 may be electrically connected to an external circuit through the conductive features 132. In some embodiments, the dielectric layer 131 includes or is made of a low-k dielectric material. In some embodiments, the dielectric layer 131 includes or is made of silicon oxide, silicon oxycarbide, silicon oxynitride, phosphosilicate glass (PSG), borosilicate glass (BSG), borophosphosilicate glass (BPSG), undoped silicate glass (USG), fluorinated silicate glass (FSG), silicon oxycarbide (SiOC), spin-on-glass (SOG), fluorine-doped silicon oxide, carbon-doped silicon oxide, porous silicon oxide, porous carbon-doped silicon oxide, other suitable low-k dielectric materials, or combinations thereof. In some embodiments, each of the conductive features 132 may be configured as a conductive via which is connected to a conductive line (not shown) that is located therebeneath. In some other embodiments, each of the conductive features 132 may be configured as a conductive contact which is connected to a gate electrode or a source/drain portion of a corresponding one of the semiconductor devices 12. In some embodiments, each of the conductive features 132 includes or is made of Co, Cu, Ni, Ru, W, Mo, Ti, Al, Ir, Rh, Zr, Ta, Zn, alloys thereof, graphene, other suitable conductive materials, or combinations thereof. In some embodiments, the conductive features 132 may be formed by a single damascene process.

Referring to FIGS. 8A to 8C, the interconnect structure 2 includes an interconnecting layer (Mx), an interconnecting layer (Vx), and an interconnecting layer (Mx+1) sequentially disposed on the base structure 10 in a Z direction, where x is an integer greater than or equal to zero.

The interconnecting layer (Mx) includes a dielectric layer 21 and metal lines 22 formed in the dielectric layer 21. In some embodiments, each of the conductive features 132 is connected to a corresponding one of the metal lines 22. Each of the metal lines 22 extends lengthwise in a Y direction transverse to the Z direction, and has a first width measured in an X direction transverse to the Y and Z directions. The metal lines 22 are spaced apart from each other in the X direction, and arranged at a first pitch S1. In some embodiments, the X, Y and Z directions are perpendicular to each other.

The interconnecting layer (Mx+1) includes an etch stop layer 40, a dielectric layer 41 formed on the etch stop layer 40, and metal lines 42 formed in the dielectric layer 41 and extending through the etch stop layer 40 in the Z direction. Each of the metal lines 42 extends lengthwise in the X direction that is transverse to the lengthwise direction (i.e., the Y direction) of each of the metal lines 22, and has a second width measured in the Y direction. The metal lines 42 are spaced apart from each other in the Y direction, and arranged at a second pitch S2. In some embodiments, the second width is less than the first width, and the second pitch S2 is less than the first pitch S1, as shown in FIG. 8C. Possible dielectric materials suitable for the dielectric layers 21, 41 are the same as or similar to those for the dielectric layer 131, and possible conductive materials suitable for the metal lines 22, 42 are the same as or similar to those for the conductive features 132, and thus the details thereof are omitted for the sake of brevity. The etch stop layer 40 includes or is made of a dielectric material that is different from the dielectric material of the dielectric layer 41. The etch stop layer 40 may be configured as a single layer structure or a multi-layered structure. In some embodiments, the etch stop layer 40 includes or is made of, for example, but not limited to, metal oxide (which includes oxides of, for example, but not limited to, aluminum, zirconium, hafnium, or combinations thereof), metal nitride, metal oxynitirde, silicon oxide, silicon nitride, silicon oxynitride, silicon oxycarbide, silicon carbon nitride, silicon oxycarbon nitride, other suitable materials, or combinations thereof.

The interconnecting layer (Vx), which is disposed between the interconnecting layer (Mx) and the interconnecting layer (Mx+1), includes an etch stop layer 30, a dielectric layer 31 disposed on the etch stop layer 30, contact vias 32 disposed in the dielectric layer 31 and extending through the etch stop layer 30 in the Z direction, and doped layers 33. Each of the doped layers 33 is disposed between the dielectric layer 31 and a respective one of the contact vias 32, and serves as an etch stop layer during formation of via openings for forming the contact vias 32 respectively therein. The contact vias 32 are spaced apart from each other. Each of the contact vias 32 is disposed to connect one of the metal lines 22 to a corresponding one of the metal lines 42.

Possible materials suitable for the etch stop layer 30, the dielectric layer 31 and the conductive vias 32 are respectively the same as or similar to those for the etch stop layer 40, the dielectric layer 131 and the conductive features 132, and thus the details thereof are omitted for the sake of brevity. The dielectric material of the etch stop layer 30 is different from the dielectric material of the dielectric layer 31.

Each of the contact vias 32 has a central axis C0 and has a sidewall surface 32s which extends in a direction of the central axis C0. In some embodiments, the central axis C0 extends in the Z direction. A projection of each of the contact vias 32 on the substrate 11 has a periphery with an elliptical shape, as shown in FIGS. 8C and 8D. As used herein, the term “elliptical shape” encompasses oval, oval-like, elliptical, elliptical-like, obround, obround-like, or any other shapes that slightly deviate from elliptical shape due to process variation.

The elliptical shape has a dimension D1 projected on an imaginary plane P1, and a dimension D2 projected on an imaginary plane P2.

The imaginary plane P1 and the imaginary plane P2 are normal to an upper surface 11s of the substrate 11 and intersect with each other at the central axis C0. The imaginary plane P1 is oriented such that the lengthwise direction of each of the metal lines 22 (i.e., the Y direction) is parallel to the imaginary plane P1. The imaginary plane P2 is oriented such that the lengthwise direction of each of the metal lines 42 (e.g., the X direction) is parallel to the imaginary plane P2.

In some embodiments, as shown in FIG. 8C, in the case that the first pitch S1 of the metal lines 22 is greater than the second pitch S2 of the metal lines 42, the dimension D2 (measured in the X direction) of each of the contact vias 32 is greater than the dimension D1 (measured in the Y direction). That is, each of the contact vias 32 is configured to extend along the lengthwise direction of each of the metal lines 42 (i.e., the X direction), thereby increasing a contact area between each of the contact vias 32 and a corresponding one of the metal lines 22, 42. Since a distance between two adjacent ones of the contact vias 32 in the Y direction is sufficiently wide, a performance degradation related to time-dependent dielectric breakdown (TDDB) may be prevented.

Furthermore, as shown in FIGS. 8A and 8C, an upper surface of each of the metal lines 22 has two edges 22E opposite to each other in a widthwise direction of each of the metal lines 22 (i.e., the X direction). Each of the contact vias 32 is prevented from extending beyond the two edges 22E of a corresponding one of the metal lines 22 located therebeneath.

The imaginary plane P1 intersects the sidewall surface 32s to form two imaginary lines QL1, and the imaginary plane P2 intersects the sidewall surface 32s to form two imaginary lines QL2.

Each of the doped layers 33 includes a selected species. In some embodiments, the doped layers 33 are respectively formed from doped regions of the dielectric layer 31, and thus each of the doped layers 33 further includes elements for forming the dielectric layer 31. Hereinafter, the dielectric layer 31 refers to a dielectric layer without additional introduction of the selected species. In some embodiments, the selected species includes boron, carbon, nitrogen, phosphorus, oxygen, sulfur, aluminum, chromium, cobalt, or combinations thereof. It is noted that the selected species in each of the doped layers 33 has an average concentration that is greater than a concentration of the selected species in the dielectric layer 31.

Each of the doped layers 33 includes two doped portions 331, 332 which are separated from each other by a respective one of the contact vias 32. In some embodiments, as shown in FIGS. 8C and 8D, when the metal lines 42 are arranged at a relatively small pitch with respect to the metal lines 22, the two doped portions 331, 332 are formed opposite to each other in a widthwise direction of each of the metal lines 42 (i.e., the Y direction). In other words, the two doped portions 331, 332 are formed opposite to each other with respect to the imaginary plane P2. In some embodiments, each of the two doped portions 331, 332 has thicknesses (T) which are measured in radial directions relative to the central axis C0, and which gradually decrease along an annular direction around the central axis C0 from a respective one of the two imaginary lines QL1 to each of the two imaginary lines QL2. In some embodiments, the selected species in each of the two doped portions 331, 332 has concentrations gradually decreasing along the annular direction from the respective one of the two imaginary lines QL1 to each of the two imaginary lines QL2. With the provision of the doped layers 33, each of the contact vias 32 is prevented from expanding along the widthwise direction of each of the metal lines 42 (i.e., the Y direction).

The interconnect structure 2′ shown in FIGS. 10A to 10C has a structure substantially similar to that of the interconnect structure 2 shown in FIGS. 8A to 8C, but has differences described hereinafter. The first width of each of the metal line 22 is less than the second width of each of the metal lines 42, and the first pitch S1 of the metal lines 22 is less than the second pitch S2 of the metal lines 42. In such case, the two doped portions 331, 332 of each of the doped layers 33 are opposite to each other in the widthwise direction of a corresponding one of the metal lines 22 (i.e., the X direction). In other words, the two doped portions 331, 332 are opposite to each other with respect to the imaginary plane P1. Since each of the contact vias 32 is prevented from expanding along the widthwise direction of each of the metal lines 22 (i.e., the X direction) by a respective one of the doped layers 33, and since each of the contact vias 32 is configured to extend in the lengthwise direction of each of the metal lines 22 (i.e., the Y direction), the dimension D1 (measured in the Y direction) of each of the contact vias 32 is greater than the dimension D2 (measured in the X direction), thereby increasing a contact area between each of the contact vias 32 and a corresponding one of the metal lines 22, 42. Since a distance between two adjacent ones of the contact vias 32 in the X direction is sufficiently wide, a performance degradation related to TDDB may be prevented.

Furthermore, as shown in FIGS. 10B and 10C, each of the metal lines 42 has two edges 42E opposite to each other in the widthwise direction of each of the metal lines 42 (i.e., the Y direction). Each of the contact vias 32 is prevented from extending beyond the two edges 42E of a corresponding one of the metal lines 42 located thereabove.

The details on formation of the interconnect structures 2, 2′ will be described hereinafter. Similar numerals from the above-mentioned embodiments have been used where appropriate, with some construction differences being indicated with different numerals.

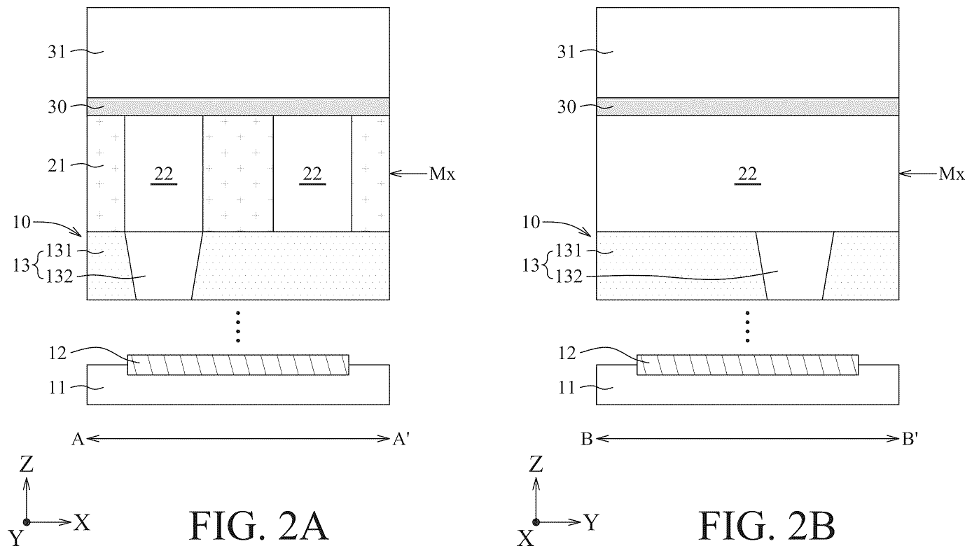

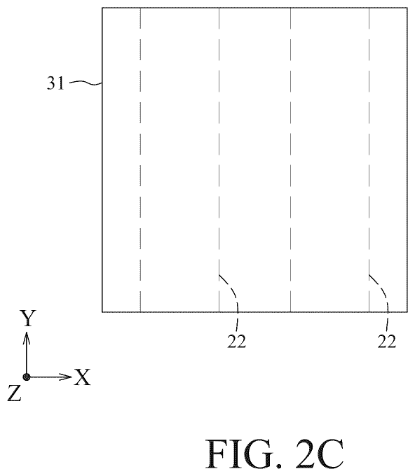

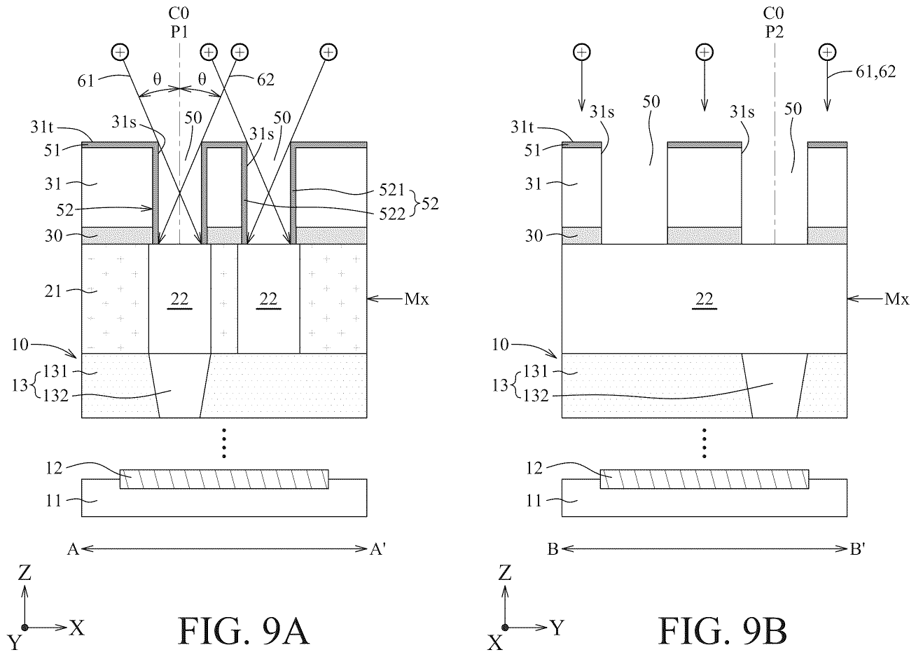

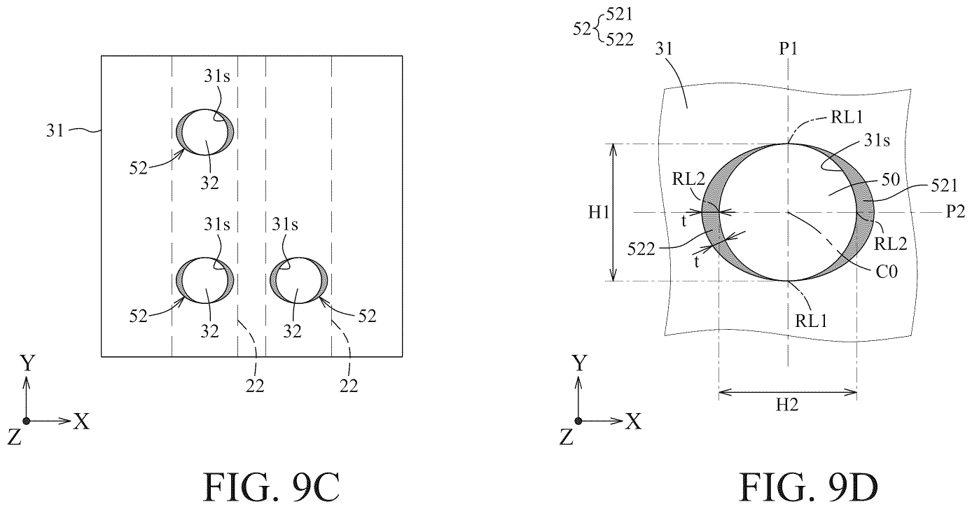

The method 1 may include steps S01 to S06. FIGS. 2A to 8D are schematic views illustrating intermediate stages of the method 1 in accordance with some embodiments, in which the interconnect structure 2 is formed, and FIGS. 9A to 10D are schematic views illustrating intermediate stages of the method 1 in accordance with some other embodiments, in which the interconnect structure 2′ is formed.

FIGS. 2A, 3A, 4A, 5A, 6A, and 7A are each a schematic cross sectional view similar to that of FIG. 8A, and FIGS. 2B, 3B, 4B, 5B, 6B, and 7B are each a schematic cross sectional view similar to that of FIG. 8B, but illustrating formation of the interconnect structure 2 at different intermediate stages of the method 1.

Referring to FIG. 1 and the examples illustrated in FIGS. 2A to 2C, the method 1 begins at step S01, where the etch stop layer 30 and the dielectric layer 31 are formed sequentially on the interconnecting layer (Mx) opposite to the substrate 11. FIG. 2C is a schematic top view illustrating the structure shown in FIGS. 2A and 2B.

In some embodiments, formation of the interconnecting layer (Mx) may include forming the dielectric layer 21 on the base structure 10 by ALD, CVD, PVD, or other suitable deposition techniques, patterning the dielectric layer 21 to form trenches (not shown) therein by a photolithography process and a subsequent etching process, and forming the metal lines 22 respectively in the trenches using ALD, CVD, PVD, or other suitable deposition techniques, followed by a planarization process (e.g., chemical mechanical polishing) to expose the dielectric layer 21. In some alternative embodiments, the dielectric layer 21 may be formed after formation of the metal lines 22. Other back-end-of-line (BEOL) techniques suitable for forming the interconnecting layer (Mx) are within the contemplated scope of the present disclosure.

In some embodiments, formation of the etch stop layer 30 and the dielectric layer 31 includes ALD, CVD, PVD, or other suitable deposition techniques. In some embodiments, the etch stop layer 30 has a thickness ranging from about 30 Å to about 100 Å, but other ranges of values are also within the contemplated scope of the present disclosure.

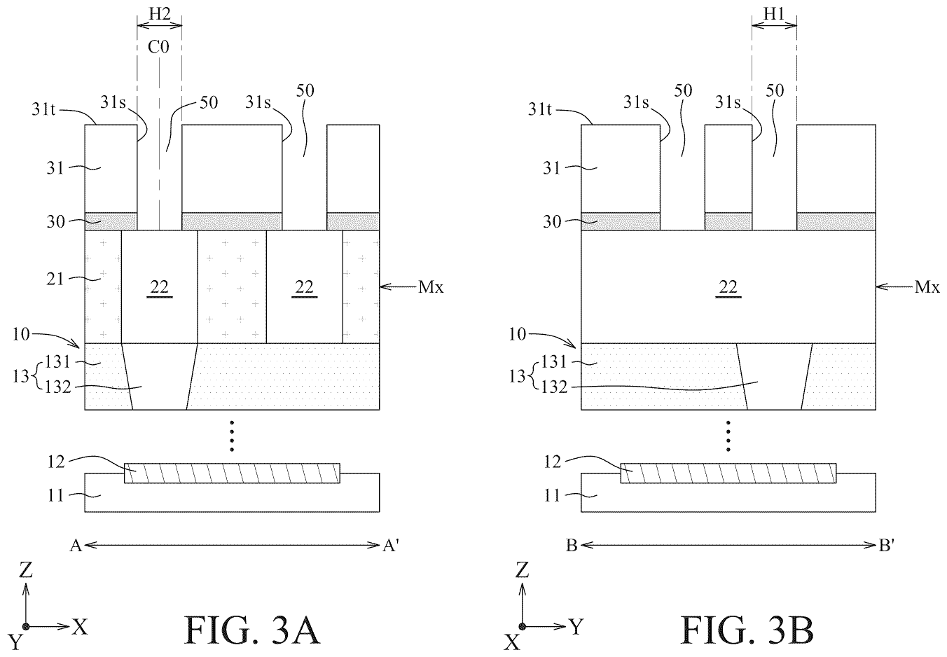

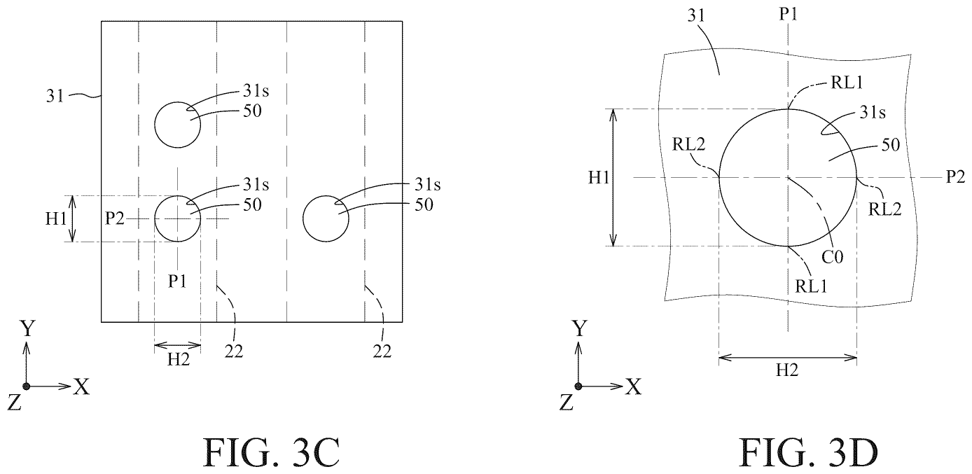

Referring to FIG. 1 and the examples illustrated in FIGS. 3A to 3D, the method 1 proceeds to step S02, where the dielectric layer 31 is patterned to form via openings 50 therein. FIG. 3A to 3C are schematic views respectively similar to those of FIGS. 2A to 2C, but illustrating the structures after step S02. FIG. 3D is an enlarged fragmentary top view illustrating one of the via openings 50 shown in FIG. 3C.

In some embodiments, formation of the via openings 50 includes a photolithography process, followed by a first etching process. In some embodiments, the first etching process includes an anisotropic etching process such as a plasma etching process, in which a first plasma is used to etch the dielectric layer 31. A first precursor gas used to generate the first plasma may include a first etching gas and a first carrier gas. The first etching gas includes a halogen-containing gas (such as a fluorine-containing gas, a chlorine-containing gas, a bromine-containing gas, or combinations thereof), CH₄, N₂, O₂, H₂, or combinations thereof. In some embodiments, the halogen-containing gas includes HBr, Cl₂, CF₄, CHF₃, CH₃F, CH₂F₂, C₄F₈, C₄F₆, SF₆, other suitable halogen-containing gases, or combinations thereof. In the first etching gas, the ratio of a number of carbon atoms to a number of halogen atoms (e.g., F, Cl, Br, I, or combinations thereof) may be referred to as a carbon to halogen ratio. In some embodiments, the carbon to halogen ratio of the first etching gas is less than about 5. When the carbon to halogen ratio of the first etching gas is too large (e.g., greater than about 5), formation and/or re-deposition of byproducts may exceed etching of the dielectric layer 31, thereby adversely affecting formation of the via openings 50. The first carrier gas is provided to adjust the concentration of the first etching gas in the first precursor gas, and may include an inert gas, such as He, Ne, Ar, Kr, or combinations thereof. In some embodiments, a plasma generator for generating the first plasma includes an inductively-coupled plasma (ICP) generator, a capacitively-coupled plasma (CCP) generator, an electron cyclotron resonance (ECR) plasma generator, or other suitable plasma generators. In some embodiments, the first plasma is generated from the first precursor gas with a plasma source power ranging from about 100 W to about 2000 W. In some embodiments, the first etching process is performed using a bias voltage ranging from about 100 V to about 1200 V, so that ions in the first plasma is directed toward the substrate 11 to thereby remove portions of the dielectric layer 31 that are not protected by a patterned photoresist layer (not shown). Other patterning techniques suitable for forming the via openings 50 are also within the contemplated scope of the present disclosure.

Each of the via openings 50 is located above a corresponding one of the metal lines 22. In some embodiments, each of the via openings 50 is formed to penetrate the etch stop layer 30 so as to expose the corresponding one of the metal lines 22. It is noted that the dielectric layer 21 is prevented from being exposed to the via openings 50. In some embodiments not shown herein, each of the via openings 50 may terminate at the etch stop layer 30 so that each of the metal lines 22 are protected by the etch stop layer 30.

After step S02, the dielectric layer 31 has a top surface 31t and inner wall surfaces 31s which are connected to the top surface 31t and which extend downwardly toward the substrate 11, as shown in FIGS. 3A and 3B.

Each of the via opening 50 is defined by a respective one of the inner wall surfaces 31s, and has a central axis C0. Since the central axis of each of the via openings 50 is substantially aligned with the central axis of a respective one of the contact vias 32, the central axis of each of the via openings 50 is also denoted by C0. Each of the inner wall surfaces 31s extends in the direction of the central axis C0 (i.e., the Z direction). A projection of each of the inner wall surfaces 31s on the substrate 11 has an annular shape, as shown in FIGS. 3C and 3D. As used herein, the term “annular shape” encompasses rounded, circular, circular-like, elliptical, elliptical-like, obround, obround-like, or any other annular shapes.

The annular shape has a dimension H1 projected on the imaginary plane P1 and a dimension H2 projected on the imaginary plane P2. The imaginary plane P1 intersects with the inner wall surface 31s to form two imaginary lines RL1. The imaginary plane P2 intersects with the inner wall surface 31s to form two imaginary lines RL2. In some embodiments, the dimension H1 (measured in the Y direction) is substantially equal to the dimension H2 (measured in the X direction). In some embodiments not shown herein, the dimension H2 may be slightly greater than the dimension H1 by adjusting process parameters of the photolithography process for forming the via openings 50.

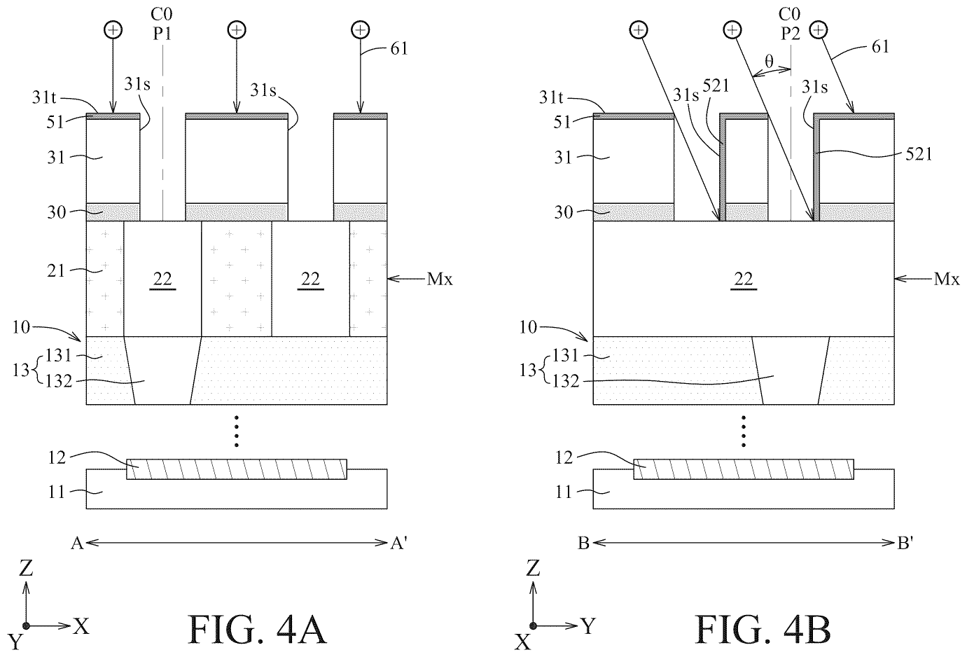

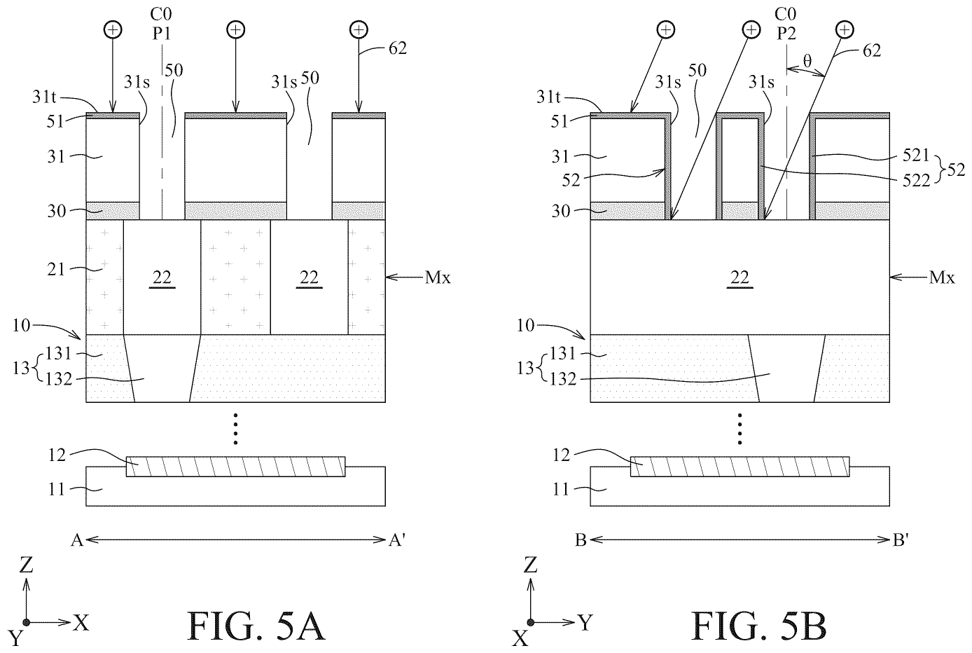

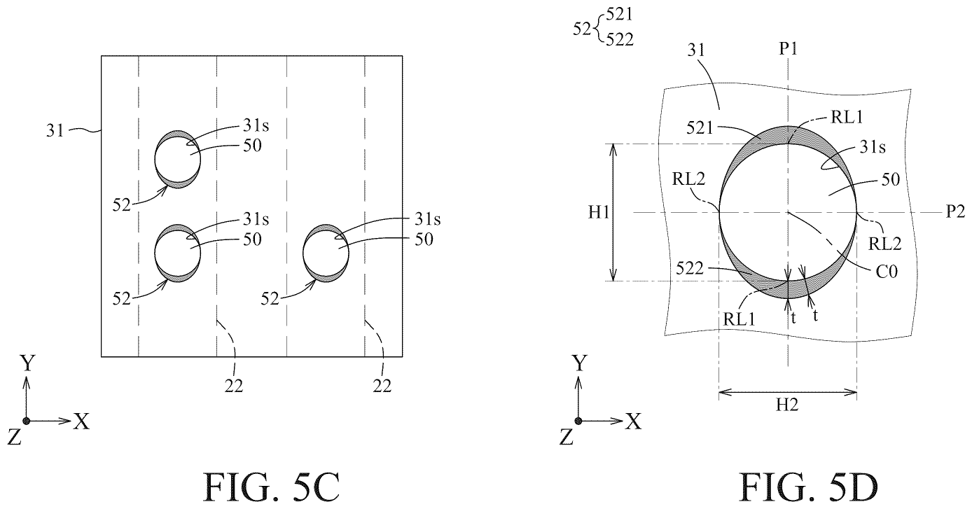

Referring to FIG. 1 and the examples illustrated in FIGS. 4A to 5D, the method 1 proceeds to step S03, where the inner wall surfaces 31s are subjected to an etch rate modification treatment, so that each of the inner wall surfaces 31s has etching rates gradually increasing from each of the two imaginary lines RL1 to each of the two imaginary lines RL2. FIG. 5A to 5D are schematic views respectively similar to those of FIGS. 3A to 3D, but illustrating the structures after step S03. FIGS. 4A and 4B illustrate a possible intermediate state in step S03 in accordance with some embodiments.

In some embodiments, after the etching rate modification treatment, a ratio of a maximum value of the etching rates of the inner wall surface 31s to a minimum value of the etching rates of the inner wall surface 31s is greater than about 6. In some embodiments, the maximum value of the etching rates of the inner wall surface 31s occurs at the two imaginary lines RL2 (see FIG. 5D). In some embodiments, the minimum value of the etching rates of the inner wall surface 31s occurs at the two imaginary lines RL1. When the ratio of the maximum value of the etching rates of the inner wall surface 31s to the minimum value of the etching rates of the inner wall surface 31s is less than a certain value (e.g., about six), or when the minimum value of the etching rates of the inner wall surface 31s is not small enough, the dimension H1 may be elongated to an undesired value during an etching process in step S04, thereby causing a performance degradation related to TDDB.

In some embodiments, the etch rate modification treatment includes a directional doping treatment. To be specific, the directional doping treatment is performed on the dielectric layer 31 so as to form a doped region 51 and doped regions 52 (see FIGS. 5A and 5B). The doped region 51 extends into the dielectric layer 31 from the top surface 31t, and each of the doped regions 52 extends into the dielectric layer 31 from a corresponding one of the inner wall surfaces 31s. Each of the doped regions 51, 52 includes the selected species (i.e., boron, carbon, nitrogen, phosphorus, oxygen, sulfur, aluminum, chromium, cobalt, or combinations thereof). It should be noted that the doped region 51 is not shown in FIGS. 5C and 5D.

Referring to FIGS. 5C and 5D, the selected species in each of the doped regions 52 has concentrations gradually decreasing along the annular direction from each of the two imaginary lines RL1 to each of the two imaginary lines RL2. Each of the doped regions 52 has thicknesses (t) which are measured in radial directions relative to the central axis C0, and which gradually decrease along the annular direction from each of the two imaginary lines RL1 to each of the two imaginary lines RL2. In some embodiments, each of the doped regions 52 includes two doped zones 521, 522 opposite to each other with respect to the imaginary plane P2. In some embodiments, a maximum value of the thicknesses (t) of each of the doped regions 52 ranges from about 5 Å to about 30 Å. In some embodiments, a maximum value of the concentrations of the selected species in each of the doped regions 52 ranges from about 100 ppm to about 300000 ppm. When the maximum value of the thicknesses (t) of each of the doped regions 52 is too large (e.g., greater than about 30 Å), or when the maximum value of the concentrations of the selected species in each of the doped regions 52 is too large (e.g., greater than about 300000 ppm), the performance related to TDDB may be adversely affected due to excess of the selected species in the dielectric layer 31. Furthermore, when the maximum value of the thicknesses (t) of each of the doped regions 52 is too small (e.g., less than about 5 Å), or when the maximum value of the dopant in each of the doped regions 52 is too small (e.g., less than about 100 ppm), the ratio of the maximum value of the etching rates of the inner wall surface 31s to the minimum value of the etching rates of the inner wall surface 31s may be less than about 6, thereby adversely affecting the performance related to TDDB.

In some embodiments, the directional doping treatment (step S03) includes directing ion beams 61, 62 incident upon the inner wall surfaces 31s at a tilt angle (θ) relative to the imaginary plane P2, as shown in FIGS. 4B and 5B. In addition, the ion beams 61, 62 are directed in an incident direction parallel to the imaginary plane P1, as shown in FIGS. 4A and 5A. To be specific, the incident direction of the ion beams 61 and the incident direction of the ion beams 62 are tilted in opposite directions relative to the imaginary plane P2. For example, the incident direction of the ion beams 61 is tilted counter-clockwise from the imaginary plane P2 (see FIGS. 4A and 4B), and the incident direction of the ion beams 62 is tilted clockwise from the imaginary plane P2 (see FIGS. 5A and 5B). The ion beams 61 are directed incident upon the inner wall surfaces 31s to form the doped zones 521 of the doped regions 52, and the ion beams 62 are directed incident upon the inner wall surfaces 31s to form the doped zones 522 of the doped regions 52. In some embodiments, the tilt angle (θ) ranges from about 10 degrees to about 60 degrees. The tilt angle (θ) may vary according to an aspect ratio of each of the via openings 50. To be specific, when a ratio of a height (measured in the Z direction) to the dimension H1 (measured in the Y direction) of each of the via openings 50 is higher, the tilt angle (θ) may be lower, and vice versa.

In some embodiments, during the directional doping treatment, a substrate retainer for supporting the substrate 11 is rotatable about the X direction to adjust the tilt angle (θ).

In some embodiments, the directional doping treatment is performed by an implantation process using an ion implanter. The ion implanter includes an ion filter for filtering a plasma of a plurality of ion species so as to obtain the ion beams 61, 62 including the selected species without other impurities. In some embodiments, each of the ion beams 61, 62 is provided with an energy ranging from about 1 keV to about 10 keV. In some embodiments, a dosage of each of the ion beams 61, 62 ranges from about 1E13 atoms/cm² to about 1E16 atoms/cm². After the implantation process, a thermal treatment may be performed at a temperature ranging from about 250° C. to about 450° C. for a time period ranging from about 60 seconds to about 600 seconds. When the energy of each of the ion beams 61, 62 is too large (e.g., greater than about 10 keV), the maximum value of the thicknesses (T) of each of the doped regions 52 may be greater than a certain value (e.g., about 30 Å). When the dosage of each of the ion beams 61, 62 is too large (e.g., greater than about 1E16 atoms/cm²), the maximum value of the concentrations of the selected species in each of the doped regions 52 may be greater than a certain value (e.g., about 300000 ppm). On the contrary, when the energy of each of the ion beams 61, 62 is too small (e.g., less than about 1 keV), the maximum value of the thicknesses (t) of each of the doped regions 52 may be less than a certain value (e.g., about 5 Å). When the dosage of each of the ion beams 61, 62 is too small (e.g., less than about 1E13 atoms/cm²), the maximum value of the concentrations of the selected species in each of the doped regions 52 may be less than a certain value (e.g., about 100 ppm).

In some alternative embodiments, the directional doping treatment is performed using an ion beam etcher. The ion beam etcher includes a process chamber, the substrate retainer which is rotatable and which is located in the process chamber, a plasma generator for generating a second plasma, and a grid which is located between the plasma generator and the process chamber. The grid is applied with a non-zero bias voltage to accelerate ions in the second plasma so as to form the ion beams 61, 62 incident toward the substrate 11 which is retained on the rotatable substrate retainer.

The second plasma is generated from a second precursor gas by the plasma generator of the ion beam etcher. The second precursor gas includes a doping gas which includes the selected species, and a second carrier gas. In some embodiments, the doping gas includes CH₄, CF₄, CHF₃, CH₃F, CH₂F₂, C₄F₈, C₄F₆, SF₆, BCl₃, AlCl₃, O₂, N₂, or combinations thereof. In some embodiments, in the doping gas, the ratio of a number of atoms of the selected species (i.e., boron, carbon, nitrogen, phosphorus, oxygen, sulfur, aluminum, chromium, cobalt, or combinations thereof) to a number of halogen atoms (e.g., F, Cl, Br, I, or combinations thereof) is greater than about 20, such that the dielectric layer 31 may be prevented from being etched or damaged. In other words, when the ratio of a number of atoms of the selected species to a number of halogen atoms is less than a certain value (e.g., about 20), the dielectric layer 31 may be etched or damaged. The second carrier gas is provided to adjust the concentration of the doping gas in the second precursor gas, and may include an inert gas, such as He, Ne, Ar, Kr, or combinations thereof. In some embodiments, the plasma generator for generating the second plasma includes an inductively-coupled plasma (ICP) generator, a capacitively-coupled plasma (CCP) generator, an electron cyclotron resonance (ECR) plasma generator, or other suitable plasma generators. In some embodiments, the second plasma is generated from the second precursor gas with a plasma source power ranging from about 100 W to about 1000 W. In some embodiments, the bias voltage used to accelerate the ion beams 61, 62 ranges from about 100 V to about 2000 V. When the bias voltage is too high (e.g., greater than about 2000 V), the maximum value of the thicknesses (t) of each of the doped regions 52 may be greater than a certain value (e.g., about 30 Å). When the plasma source power is too high (e.g., greater than about 1000 W), the maximum value of the concentrations of the selected species in each of the doped regions 52 may be greater than a certain value (e.g., about 300000 ppm). On the contrary, when the bias voltage is too low (e.g., less than about 100 V), the maximum value of the thicknesses (t) of each of the doped regions 52 may be less than a certain value (e.g., about 5 Å). When the plasma source power is too low (e.g., less than about 100 W), the maximum value of the concentrations of the selected species in each of the doped regions 52 may be less than a certain value (e.g., about 100 ppm).

It is noted that the ion beams 61, 62 generated in the ion beam etcher include the selected species and other impurities (e.g., F, Cl, He, Ne, Ar, Kr) present in the second precursor gas. Therefore, each of the doped regions 51, 52 may further include the impurities. The impurities in each of the doped regions 51, 52 has a concentration that is less than the concentration of the selected species in each of the doped regions 51, 52.

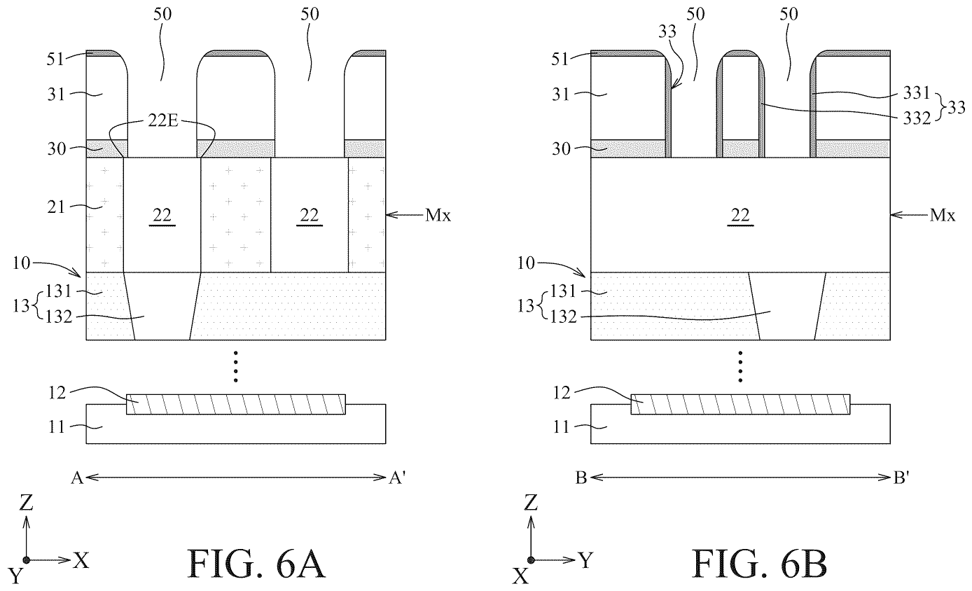

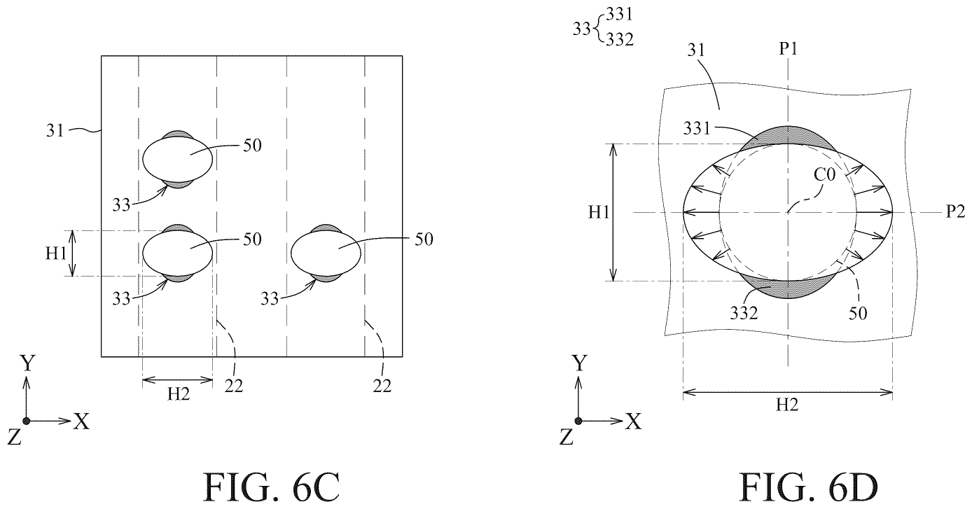

Referring to FIG. 1 and the examples illustrated in FIGS. 6A to 6D, the method 1 proceeds to step S04, where the inner wall surfaces 31s are subjected to a second etching process, so that the dimension H2 is elongated to be greater than the dimension H1. FIG. 6A to 6D are schematic views respectively similar to those of FIGS. 5A to 5D, but illustrating the structures after step S04.

Since each of the inner wall surfaces 31s is modified to have the etching rates gradually increasing from each of the two imaginary lines RL1 to each of the two imaginary lines RL2 (in step S03), the dielectric layer 31 is etched with different etch rates (shown as solid arrows), as shown in FIG. 6D. Referring to FIG. 3D (step S02) and FIG. 6D (step S04), the dimension H2 is elongated by an amount that is greater than an amount by which the dimension H1 is elongated. It is noted that, as shown in FIG. 6A, during the second etching process, a bottom of each of the via openings 50 is prevented from expanding beyond each of the two edges 22E of a corresponding one of the metal lines 22 located therebeneath by adjusting etching time in the second etching process, thereby preventing the dielectric layer 21 from being damaged during the second etching process. During the second etching process, portions of each of the doped regions 52 (see FIG. 5D), which have relatively high etch rates and which are relatively thin, are removed, so that the doped regions 52 are respectively formed into the doped layers 33.

In some embodiments, the second etching process includes a wet etching process, a dry etching process (including a gas chemical etching process, a plasma etching process, etc.), or a combination thereof. Etchant(s) used in the second etching process may be present in gas phase, liquid phase, plasma, or other suitable states. In some embodiments, wet etchant(s) used in the wet etching process may include NH₄OH, H₂SO₄, H₂O₂, HCl, H₂O, HF, HNO₃, diluted HF, O₃, H₃PO₄, other suitable etchants, or combinations thereof. In some embodiments, gaseous etchant(s) used in the gas chemical etching process may include NF₃, CF₄, C₄F₈, C₄F₆, HF, or combinations thereof. In some embodiments, the plasma etching process in step S04 may be performed in a manner similar to the plasma etching process in the step S02, but the plasma etching process in step S04 may be performed using a bias voltage ranging from about 0 V to about 1200 V. In some embodiments, in the case that the bias voltage used in step S04 is not equal to zero, the plasma etching process proceeds as a selective chemical reaction and an ion bombardment reaction, and thus top corner portions of the dielectric layer 31 that are respectively adjacent to the via openings 50 each may have a rounded corner profile, which is beneficial to filling the conductive material of the conductive vias 32 in the via openings 50 (in step S05).

In some embodiments not shown herein, in the case that each of the metal lines 22 are protected by the etch stop layer 30 before the second etching process, during the second etching process, the inner wall surface 31s may extend in the direction of the central axis C0 (i.e., the Z direction) such that each of the via openings 50 penetrates the etch stop layer 30 to expose a corresponding one of the metal lines 22. In some embodiments, prior to the second etching process, a wet clean process may be performed to remove portions of the etch stop layer 30 that are doped with the selected species, so that each of the via openings 50 may be prevented from tapering in the Z direction toward the substrate 11.

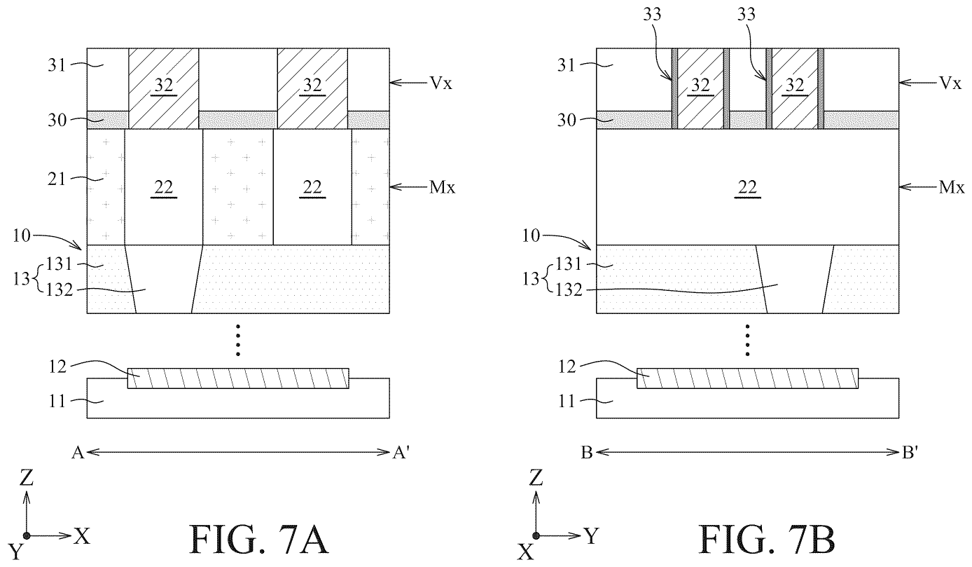

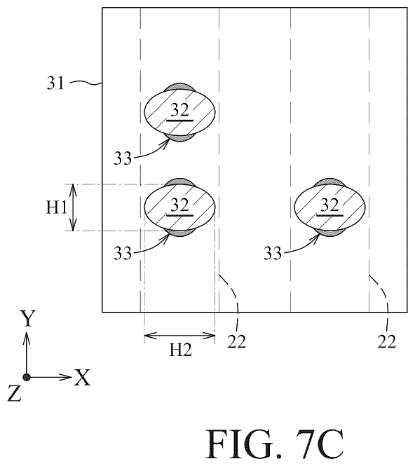

Referring to FIG. 1 and the examples illustrated in FIGS. 7A to 7C, the method 1 proceeds to step S05, where the contact vias 32 are respectively formed in the via openings 50, thereby obtaining the interconnecting layer (Vx). FIG. 7A to 7C are schematic views respectively similar to those of FIGS. 6A to 6C, but illustrating the structures after step S05.

In some embodiments, prior to formation of the contact vias 32, an etching process (such as a dry etching and/or a wet etching process) may be performed to remove portions of the metal lines 22 that are doped with the selected species, so that a contact resistance between each of the contact vias 32 and a corresponding one of the metal lines 22 may be prevented from increasing.

In some embodiments, step S05 may include depositing the conductive material of the conductive vias 32 on the dielectric layer 31 to fill the via openings 50 by ALD, CVD, PVD, or other suitable deposition techniques, and performing a planarization process (e.g., chemical mechanical polishing) until the dielectric layer 31 is exposed and the top corner portions of the dielectric layer 31 are removed. In some embodiments, a height of each of the contact vias 32 measured in the Z direction ranges from about 300 Å to about 1000 Å.

Referring to FIG. 1 and the examples illustrated in FIGS. 8A to 8D, the method 1 proceeds to step S06, where the interconnecting layer (Mx+1) is formed on the interconnecting layer (Vx). FIGS. 8A, 8B, 8C, and 8D are schematic views respectively similar to those of FIGS. 7A, 7B, 7C, and 6D, but illustrating the structures after step S06.

In some embodiments, formation of the interconnecting layer (Mx+1) may be performed in a manner similar to that for forming the interconnecting layer (Mx), and thus the details thereof are omitted for the sake of brevity. Other back-end-of-line (BEOL) techniques suitable for forming the interconnecting layer (Mx+1) are within the contemplated scope of the present disclosure. It is noted that the interconnecting layer (Vx) and the interconnecting layer (Mx+1) as described above are formed by a single damascene process. In some other embodiments not shown herein, after appropriate modifications, the interconnecting layer (Vx) and the interconnecting layer (Mx+1) may be formed by a dual damascene process, in which the contact vias 32 and the metal lines 42 are formed simultaneously. To be specific, first, trenches (not shown) for forming the metal lines 42 respectively therein are formed to be in spatial communication with the via openings 50 obtained after step S04, and then a conductive material is deposited to fill the trenches and the via openings 50 at the same time, thereby obtaining the contact vias 32 and the metal lines 42. The trenches for forming the metal lines 42 respectively therein may be formed before or after formation of the via opening 50 obtained after step S04.

In the following, formation of the interconnect structure 2′ is described. Similar numerals from the above-mentioned embodiments have been used where appropriate, with some construction differences being indicated with different numerals. The interconnect structure 2′ may be formed in a manner similar to the method 1 as described above, but has slight differences in steps S03 and S04. FIGS. 9A to 9D are schematic views respectively similar to those of FIGS. 5A to 5D, but illustrating step S03 of the method 1 for manufacturing the interconnect structure 2′ in accordance with some other embodiments, in which the ion beams 61, 62 incident upon the inner wall surfaces 31s at a tilt angle (θ) relative to the imaginary plane P1, and the incident direction of each of the ion beams 61, 62 is parallel to the imaginary plane P2. As such, the two doped zones 521, 522 of each of the doped regions 52 are formed opposite to each other with respect to the imaginary plane P1. During the second etching process (step S04), the dimension H1 is elongated to be greater than the dimension H2. In some embodiments, the dimension H1 is elongated by an amount that is greater than an amount by which the dimension H2 is elongated.

In some embodiments, some steps in the method 1 may be modified, replaced, or eliminated without departure from the spirit and scope of the present disclosure. In some alternative embodiments, the interconnect structure 2, 2′ may further include additional features, and/or some features present in the interconnect structure 2, 2′ may be modified, replaced, or eliminated without departure from the spirit and scope of the present disclosure.

In summary, with the provision of the doped regions 52, each of the contact vias 32 may be controlled to expand along the lengthwise direction of the metal lines 22 or 42 which are arranged at a relatively small pitch, and each of the contact vias 32 may be prevented from expanding along the widthwise direction of the metal lines 22 or 42 which are arranged at a relatively small pitch. Therefore, the contact area between each of the contact vias 32 and a corresponding one of the metal lines 22, 42 can be effectively increased, and a performance degradation related to TDDB can be prevented.

In accordance with some embodiments of the present disclosure, a method for manufacturing an interconnect structure includes: forming a via opening in a dielectric layer on a substrate, the via opening being defined by an inner wall surface of the dielectric layer, the inner wall surface extending in a direction of a central axis of the via opening and being formed with an annular top view shape, the annular top view shape having a first dimension in a first imaginary plane normal to the substrate and a second dimension in a second imaginary plane normal to the substrate, the second imaginary plane intersecting the first imaginary plane at the central axis, the first imaginary plane intersecting the inner wall surface to form two first imaginary lines, the second imaginary plane intersecting the inner wall surface to form two second imaginary lines; subjecting the inner wall surface of the dielectric layer to an etching rate modification treatment, so that the inner wall surface has etching rates gradually increasing from each of the two first imaginary lines to each of the two second imaginary lines; subjecting the inner wall surface of the dielectric layer to an etching process, so that the second dimension is elongated to be greater than the first dimension; and after the etching process, forming a contact via in the via opening.

In accordance with some embodiments of the present disclosure, the second dimension is elongated by an amount greater than an amount by which the first dimension is elongated.

In accordance with some embodiments of the present disclosure, the method further includes forming a first interconnecting layer below the dielectric layer. The first interconnecting layer is formed with a first metal line which is connected to the contact via, and which extends lengthwise in a first direction transverse to the direction of the central axis and parallel to the second imaginary plane.

In accordance with some embodiments of the present disclosure, the method further includes forming a second interconnecting layer on the dielectric layer opposite to the first interconnecting layer. The second interconnecting layer is formed with a second metal line which is connected to the first metal line through the contact via and which extends lengthwise in a second direction transverse to the direction of the central axis and parallel to the first imaginary plane. The second metal line has a width that is greater than a width of the first metal line.

In accordance with some embodiments of the present disclosure, the method further includes: forming a first interconnecting layer below the dielectric layer; and forming a second interconnecting layer on the dielectric layer opposite to the first interconnecting layer. The first interconnecting layer is formed with a first metal line which is connected to the contact via, and which extends lengthwise in a first direction transverse to the direction of the central axis and parallel to the first imaginary plane. The second interconnecting layer is formed with a second metal line which is connected to the first metal line through the contact via, and which extends lengthwise in a second direction transverse to the direction of the central axis and parallel to the second imaginary plane. The second metal line has a width that is less than a width of the first metal line.

In accordance with some embodiments of the present disclosure, the first metal line has two edges opposite to each other in the second direction transverse to the first direction. During the etching process, the via opening is prevented from expanding beyond each of the two edges of the first metal line.

In accordance with some embodiments of the present disclosure, after the etching rate modification treatment, a ratio of a maximum value of the etching rates of the inner wall surface to a minimum value of the etching rates of the inner wall surface is greater than 6.

In accordance with some embodiments of the present disclosure, a method for manufacturing an interconnect structure includes: forming a via opening in a dielectric layer on a substrate, the via opening being defined by an inner wall surface of the dielectric layer, the inner wall surface extending in a direction of a central axis of the via opening and being formed with an annular top view shape, the annular top view shape having a first dimension in a first imaginary plane normal to the substrate and a second dimension in a second imaginary plane normal to the substrate, the second imaginary plane intersecting the first imaginary plane at the central axis, the first imaginary plane intersecting the inner wall surface to form two first imaginary lines, the second imaginary plane intersecting the inner wall surface to form two second imaginary lines; subjecting the dielectric layer to a directional doping treatment, so as to form two doped zones which extend into the dielectric layer from the inner wall surface and which are opposite to each other with respect to the second imaginary plane, each of the two doped zones including a selected species and having thicknesses measured in radial directions relative to the central axis, the thicknesses gradually decreasing from a respective one of the two first imaginary lines to each of the two second imaginary lines; subjecting the inner wall surface of the dielectric layer to an etching process, so that the second dimension is elongated to be greater than the first dimension; and after the etching process, forming a contact via in the via opening.

In accordance with some embodiments of the present disclosure, the selected species includes boron, carbon, nitrogen, phosphorus, oxygen, sulfur, aluminum, chromium, cobalt, or combinations thereof.

In accordance with some embodiments of the present disclosure, the selected species in each of the two doped zones has concentrations gradually decreasing from the respective one of the two first imaginary lines to each of the two second imaginary lines.

In accordance with some embodiments of the present disclosure, the directional doping treatment is performed by an implantation process.

In accordance with some embodiments of the present disclosure, the directional doping treatment includes directing ion beams incident upon the inner wall surface at a tilt angle relative to the second imaginary plane. The ion beams include the selected species. The tilt angle ranges from 10 degrees to 60 degrees.

In accordance with some embodiments of the present disclosure, the ion beams are directed in an incident direction parallel to the first imaginary plane.

In accordance with some embodiments of the present disclosure, a precursor gas used to generate the ion beams includes CH₄, CF₄, CHF₃, CH₃F, CH₂F₂, C₄F₈, C₄F₆, SF₆, BCl₃, AlCl₃, O₂, N₂, or combinations thereof.

In accordance with some embodiments of the present disclosure, in the precursor gas, a ratio of a number of atoms of the selected species to a number of halogen atoms is greater than 20.

In accordance with some embodiments of the present disclosure, the ion beams is generated from the precursor gas by a plasma generator and is accelerated toward the substrate by a bias voltage ranging from 100 V to 2000 V.

In accordance with some embodiments of the present disclosure, the etching process includes a wet etching process, a dry etching process, or a combination thereof.

In accordance with some embodiments of the present disclosure, an interconnect structure includes: a dielectric layer disposed on a substrate; a contact via disposed in the dielectric layer and having a sidewall surface which extends in a direction of a central axis of the contact via, a projection of the contact via on the substrate having a periphery with an elliptical shape, the elliptical shape having a first dimension in a first imaginary plane normal to the substrate and a second dimension in a second imaginary plane normal to the substrate, the second imaginary plane intersecting the first imaginary plane at the central axis, the first imaginary plane intersecting the sidewall surface to form two first imaginary lines, the second imaginary plane intersecting the sidewall surface to form two second imaginary lines, the second dimension being greater than the first dimension; and two doped portions disposed opposite to each other with respect to the second imaginary plane, each of the two doped portions being disposed between the dielectric layer and the contact via, including a selected species, and having thicknesses measured in radial directions relative to the central axis, the thicknesses gradually decreasing from a respective one of the two first imaginary lines to each of the two second imaginary lines.

In accordance with some embodiments of the present disclosure, the selected species includes boron, carbon, nitrogen, phosphorus, oxygen, sulfur, aluminum, chromium, cobalt, or combinations thereof.

In accordance with some embodiments of the present disclosure, the selected species in each of the two doped portions has concentrations gradually decreasing from the respective one of the two first imaginary lines to each of the two second imaginary lines.

In accordance with some embodiments of the present disclosure, a method for manufacturing an interconnect structure includes: forming an interconnecting layer on a substrate, the interconnecting layer being formed with a metal line; forming a dielectric layer on the interconnecting layer opposite to the substrate; forming a via opening in the dielectric layer, the via opening being defined by an inner wall surface of the dielectric layer, the inner wall surface extending in a direction of a central axis of the via opening and being formed with an annular top view shape, the annular top view shape having a first dimension in a first imaginary plane normal to the substrate and a second dimension in a second imaginary plane normal to the substrate, the second imaginary plane intersecting the first imaginary plane at the central axis, the first imaginary plane intersecting the inner wall surface to form two first imaginary lines, the second imaginary plane intersecting the inner wall surface to form two second imaginary lines; subjecting the inner wall surface of the dielectric layer to an etching rate modification treatment, so that the inner wall surface has an etching rate gradually increasing from each of the two first imaginary lines to each of the two second imaginary lines; subjecting the inner wall surface of the dielectric layer to an etching process, so that the second dimension is elongated to be greater than the first dimension; and after the etching process, forming a contact via in the via opening to be connected to the metal line.

In accordance with some embodiments of the present disclosure, the method further includes forming an etch stop layer between the interconnecting layer and the dielectric layer. Before the etching rate modification treatment, the via opening is formed to penetrate the etch stop layer so as to expose the metal line.

In accordance with some embodiments of the present disclosure, the method further includes forming an etch stop layer between the interconnecting layer and the dielectric layer. Before the etching rate modification treatment, the via opening is formed to terminate at the etch stop layer so that the metal line is protected by the etch stop layer. During the etching process, the inner wall surface extends in the direction of the central axis such that the via opening penetrates the etch stop layer to expose the metal line.

The foregoing outlines features of several embodiments so that those skilled in the art may better understand the aspects of the present disclosure. Those skilled in the art should appreciate that they may readily use the present disclosure as a basis for designing or modifying other processes or structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing an interconnect structure, comprising:
forming a via opening in a dielectric layer on a substrate, the via opening being defined by an inner wall surface of the dielectric layer, the inner wall surface extending in a direction of a central axis of the via opening and being formed with an annular top view shape, the annular top view shape having a first dimension in a first imaginary plane normal to the substrate and a second dimension in a second imaginary plane normal to the substrate, the second imaginary plane intersecting the first imaginary plane at the central axis, the first imaginary plane intersecting the inner wall surface to form two first imaginary lines, the second imaginary plane intersecting the inner wall surface to form two second imaginary lines;
subjecting the inner wall surface of the dielectric layer to an etching rate modification treatment, so that the inner wall surface has etching rates gradually increasing from each of the two first imaginary lines to each of the two second imaginary lines;
subjecting the inner wall surface of the dielectric layer to an etching process, so that the second dimension is elongated to be greater than the first dimension; and
after the etching process, forming a contact via in the via opening.

2. The method as claimed in claim 1, wherein the second dimension is elongated by an amount greater than an amount by which the first dimension is elongated.

3. The method as claimed in claim 1, further comprising:
forming a first interconnecting layer below the dielectric layer, the first interconnecting layer being formed with a first metal line which is connected to the contact via, and which extends lengthwise in a first direction transverse to the direction of the central axis and parallel to the second imaginary plane.

4. The method as claimed in claim 3, further comprising:
forming a second interconnecting layer on the dielectric layer opposite to the first interconnecting layer, the second interconnecting layer being formed with a second metal line which is connected to the first metal line through the contact via and which extends lengthwise in a second direction transverse to the direction of the central axis and parallel to the first imaginary plane, the second metal line having a width that is greater than a width of the first metal line.

5. The method as claimed in claim 1, further comprising:
forming a first interconnecting layer below the dielectric layer, the first interconnecting layer being formed with a first metal line which is connected to the contact via, and which extends lengthwise in a first direction transverse to the direction of the central axis and parallel to the first imaginary plane; and
forming a second interconnecting layer on the dielectric layer opposite to the first interconnecting layer, the second interconnecting layer being formed with a second metal line which is connected to the first metal line through the contact via, and which extends lengthwise in a second direction transverse to the direction of the central axis and parallel to the second imaginary plane, the second metal line having a width that is less than a width of the first metal line.

6. The method as claimed in claim 5, wherein
the first metal line has two edges opposite to each other in the second direction transverse to the first direction, and
during the etching process, the via opening is prevented from expanding beyond each of the two edges of the first metal line.

7. The method as claimed in claim 1, wherein after the etching rate modification treatment, a ratio of a maximum value of the etching rates of the inner wall surface to a minimum value of the etching rates of the inner wall surface is greater than 6.

8. A method for manufacturing an interconnect structure, comprising:
forming a via opening in a dielectric layer on a substrate, the via opening being defined by an inner wall surface of the dielectric layer, the inner wall surface extending in a direction of a central axis of the via opening and being formed with an annular top view shape, the annular top view shape having a first dimension in a first imaginary plane normal to the substrate and a second dimension in a second imaginary plane normal to the substrate, the second imaginary plane intersecting the first imaginary plane at the central axis, the first imaginary plane intersecting the inner wall surface to form two first imaginary lines, the second imaginary plane intersecting the inner wall surface to form two second imaginary lines;
subjecting the dielectric layer to a directional doping treatment, so as to form two doped zones which extend into the dielectric layer from the inner wall surface and which are opposite to each other with respect to the second imaginary plane, each of the two doped zones including a selected species and having thicknesses measured in radial directions relative to the central axis, the thicknesses gradually decreasing from a respective one of the two first imaginary lines to each of the two second imaginary lines;
subjecting the inner wall surface of the dielectric layer to an etching process, so that the second dimension is elongated to be greater than the first dimension; and
after the etching process, forming a contact via in the via opening.

9. The method as claimed in claim 8, wherein the selected species includes boron, carbon, nitrogen, phosphorus, oxygen, sulfur, aluminum, chromium, cobalt, or combinations thereof.

10. The method as claimed in claim 8, wherein the selected species in each of the two doped zones has concentrations gradually decreasing from the respective one of the two first imaginary lines to each of the two second imaginary lines.

11. The method as claimed in claim 8, wherein the directional doping treatment is performed by an implantation process.

12. The method as claimed in claim 8, wherein the directional doping treatment includes directing ion beams incident upon the inner wall surface at a tilt angle relative to the second imaginary plane, the ion beams including the selected species, the tilt angle ranging from 10 degrees to 60 degrees.

13. The method as claimed in claim 12, wherein the ion beams are directed in an incident direction parallel to the first imaginary plane.

14. The method as claimed in claim 13, wherein a precursor gas used to generate the ion beams includes CH₄, CF₄, CHF₃, CH₃F, CH₂F₂, C₄F₈, C₄F₆, SF₆, BCl₃, AlCl₃, O₂, N₂, or combinations thereof.

15. The method as claimed in claim 14, wherein in the precursor gas, a ratio of a number of atoms of the selected species to a number of halogen atoms is greater than 20.

16. The method as claimed in claim 14, wherein the ion beams is generated from the precursor gas by a plasma generator and is accelerated toward the substrate by a bias voltage ranging from 100 V to 2000 V.

17. The method as claimed in claim 8, wherein the etching process includes a wet etching process, a dry etching process, or a combination thereof.

18. An interconnect structure, comprising:
a dielectric layer disposed on a substrate;
a contact via disposed in the dielectric layer and having a sidewall surface which extends in a direction of a central axis of the contact via, a projection of the contact via on the substrate having a periphery with an elliptical shape, the elliptical shape having a first dimension in a first imaginary plane normal to the substrate and a second dimension in a second imaginary plane normal to the substrate, the second imaginary plane intersecting the first imaginary plane at the central axis, the first imaginary plane intersecting the sidewall surface to form two first imaginary lines, the second imaginary plane intersecting the sidewall surface to form two second imaginary lines, the second dimension being greater than the first dimension; and
two doped portions disposed opposite to each other with respect to the second imaginary plane, each of the two doped portions being disposed between the dielectric layer and the contact via, including a selected species, and having thicknesses measured in radial directions relative to the central axis, the thicknesses gradually decreasing from a respective one of the two first imaginary lines to each of the two second imaginary lines.

19. The interconnect structure as claimed in claim 18, wherein the selected species includes boron, carbon, nitrogen, phosphorus, oxygen, sulfur, aluminum, chromium, cobalt, or combinations thereof.

20. The interconnect structure as claimed in claim 18, the selected species in each of the two doped portions has concentrations gradually decreasing from the respective one of the two first imaginary lines to each of the two second imaginary lines.
